(19) United States
(12) Patent Application Publication
(10) Pub. No.: US 2022/0302913 A1
(43) Pub. Date: Sep. 22, 2022

(54) HIGH-SPEED DIGITAL SIGNAL DRIVER WITH LOW POWER CONSUMPTION

(71) Applicant: Infineon Technologies AG, Neubiberg (DE)

(72) Inventor: Oleg Vitrenko, Villach (AT)

(21) Appl. No.: 17/676,994

(22) Filed: Feb. 22, 2022

(30) Foreign Application Priority Data
Mar. 19, 2021 (DE) 10 2021 106 834.7
May 6, 2021 (DE) 10 2021 111 796.8

(51) Int. Cl. H03K 17/042

(52) U.S. Cl. CPC H03K 17/04206

(57) ABSTRACT

The present disclosure provides an inverter driver circuit including: an input configured to receive an input signal; an output configured to provide an output signal; a parallel circuit between the input and the output, wherein the parallel circuit includes a first circuit path parallel to a second circuit path between the input and the output, wherein the first circuit path includes an output sustaining circuit and the second circuit path includes an output driving circuit; and an inverting delay circuit coupled to the output of the inverter driver circuit and coupled to the output driving circuit, wherein the inverting delay circuit is configured to provide a control signal to the output driving circuit, wherein the control signal is a delayed and inverted version of the output signal.

### REFERENCE TO RELATED APPLICATIONS

This application claims priority to German Application number 10 2021 106 834.7, filed on Mar. 19, 2021 and German Application number 10 2021 111 796.8, filed on May 6, 2021. The contents of the above-referenced patent applications are hereby incorporated by reference in their entirety.

### TECHNICAL FIELD

The present disclosure relates to digital signal drivers, e.g., inverters.

### BACKGROUND

Various embodiments generally may relate to the field of digital circuits.

### BRIEF DESCRIPTION OF THE DRAWINGS

Throughout the figures in the drawings, identical or similar components are provided with the same reference signs. The figures are not necessarily drawn to scale. Various aspects of the present disclosure are explained below by means of various embodiments with reference to the following drawings.

FIG. 1 is a schematic diagram illustrating a conventional inverter driver circuit.

FIG. 2 is a schematic diagram illustrating a digital signal driver circuit in accordance with various aspects of the present disclosure.

FIG. 3 is another schematic diagram illustrating a digital signal driver circuit in accordance with various aspects of the present disclosure.

FIG. 4 is a timing diagram illustrating signal transitions of the digital signal driver circuit of FIG. 2 for three transition periods in accordance with various aspects of the present disclosure.

FIG. 5 is a schematic diagram illustrating a first circuit portion of the digital signal driver circuit of FIG. 2 in accordance with various aspects of the present disclosure.

FIG. 6 is a transient response diagram comparing the signal transitions of a conventional inverter driver circuit to the signal transitions of the digital signal driver circuit of FIG. 2 in accordance with various aspects of the present disclosure.

### DETAILED DESCRIPTION

The following detailed description refers to the accompanying drawings that show, by way of illustration, example details and aspects in which the present disclosure may be practiced. The same reference numbers may be used in different drawings to identify the same or similar elements. In the following description, for purposes of explanation and not limitation, specific details are set forth such as particular structures, architectures, interfaces, techniques, etc. in order to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail. For the purposes of the present document, the phrase “A or B” means (A), (B), or (A and B).

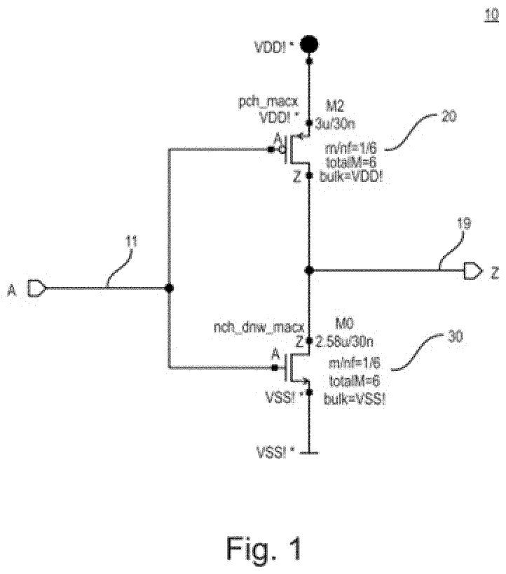

As digital circuits become more complex and portable, low-power high-speed digital signal drivers are needed to provide improved signal integrity between lower drive outputs and higher loads. For example, a conventional digital signal driver may be a simple inverter circuit. FIG. 1 illustrates a simple CMOS inverter driver. Referring to FIG. 1, a simple classic CMOS inverter driver includes a PMOS transistor 20 and an NMOS transistor 30. The source of the PMOS transistor 20 is connected to logic high VDD and the source of the NMOS transistor is connected to logic low VSS. The gates of the PMOS and NMOS transistors are connected to each other and serve as the input 11 to the inverter circuit. The sinks of the PMOS and NMOS transistors are connected to each other and serve as the output 19 of the inverter circuit. The transistors are sized to drive a load connected at output 19. For example, the PMOS transistor 20 may have a gate (channel) length of 3 micrometers and a gate (channel) width of 30 nanometers and the NMOS transistor 30 may have a gate (channel) length of 2.58 micrometers and a gate (channel) width of 30 nanometers. In a classic CMOS inverter driver, the input capacitance is equal to the sum of the capacitances of the PMOS and NMOS gates. The capacitance of a gate is determined in part by the size of the gate, and thus, the larger the gates the larger the input capacitance of the classic inverter and the slower the transition. That is, due to a slowed-down input caused by a large input capacitance, some charge is initially burned in cross-current during the transition period and only later the charge goes to recharge the output capacitance. Accordingly, the classic CMOS inverter driver suffers from excessive power consumption due to the power burned in the cross-current during the transition period when both the PMOS and NMOS transistors are active and conducting. Additionally, the classic CMOS inverter driver also has a delayed response on the output recharge when the input transitions.

The present disclosure describes circuitry to provide a digital signal driver (e.g., an inverter driver) that is faster, has lower input capacitance, consumes less power than current digital signal drivers, and scalable. The present disclosure describes an inverter driver having a sustaining portion including a set of output sustaining transistors and a driving portion including a set of output driving transistors controlled by a feedback control signal. This disclosure describes circuitry that uses the feedback control signal to dynamically connect and disconnect the output driving transistors of an inverter driver in order to reduce input capacitance, reduce power consumption, reduce output impedance, and increase performance speed. For example, by disconnecting one of the output driving transistors from the input during the transient state, the input capacitance may be reduced while transmitting a signal. For another example, by disconnecting one of the output driving transistors during the transient state, the performance speed may be improved due to faster output recharge/discharge. That is, the connected output driving transistor only has to recharge/discharge its output capacitance without “counteracting” with the opposing output driving transistor with the cross-current. Consequently, power consumption is reduced because power is mainly used for output capacitance recharge/discharge and because much less power is consumed in cross-current. Additionally, the reduced cross-current and power consumptions result in fewer disturbances created or caused by mutual inductances and mutual capacitances and thus the overall system cross-talk immunity is improved. These benefits come at the expense of a larger consumed layout area.

By way of example, this disclosure provides circuitry for a low-power, high-speed, noise immune inverter driver. Examples of the present disclosure describe an inverter driver circuit having output sustaining transistors, output driving transistors, control transistors, and delay transistors. For example, the output sustaining transistors may include a PMOS transistor and an NMOS transistor that are primarily used to sustain or maintain the output during a non-transitioning period. The output driving transistors may include a PMOS transistor and an NMOS transistor that are used to drive the output during the transitioning period and are otherwise inactive during the non-transitioning period. The control and delay transistors are used to independently connect (i.e., activate) and disconnect (i.e., deactivate) each respective output driving transistor depending on the transition direction, e.g., logic high to logic low or logic low to logic high.

Examples of the present disclosure described herein provide several advantages over a classic inverter driver. For example, examples of the present disclosure have reduced or no burned power attributed to a cross-current when the output driving transistors are in an “ON” state during transition. This permits less power consumption for the same performance. Examples of the present disclosure have improved output response. The output starts moving earlier than in a classic inverter driver since there is no counteraction by the opposite transistor during the transition period. This allows the inverter driver presented herein to operate at a slightly faster speed than the classic inverter in dedicated technology. Additionally, the absence of a cross-current and the absence of transistor counteractions leads to reduced supply-related jitter pick-up. This leads to cleaner signal propagation among a chain composed of the inverter drivers described herein. Examples of the present disclosure also have improved input response. The input moves (e.g., transitions) faster than in a classic inverter driver since there is less capacitive load. That is, there is reduced input capacitance because the amount of gate area connected to the input during the transitioning period is smaller than the amount of gate area of a classic inverter. The reduction in input capacitance creates less load for the previous stage and allows the input to transition or move faster. Examples of the present disclosure have a larger layout area than a classic inverter.

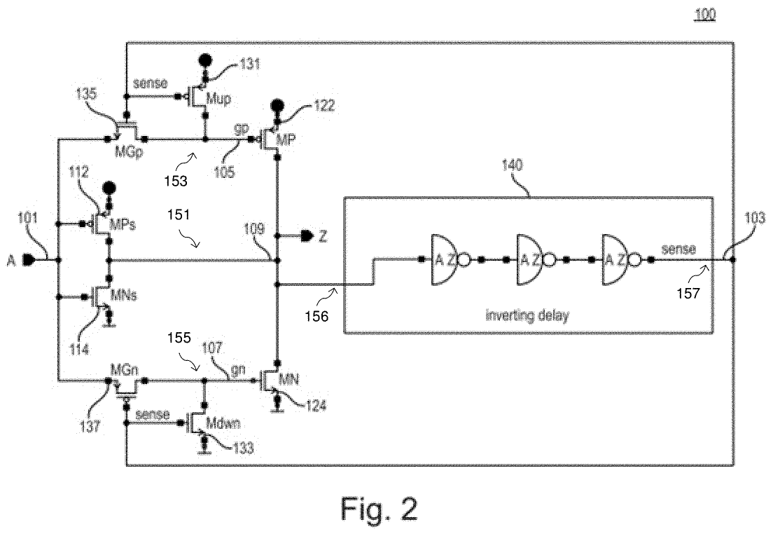

FIG. 2 is a schematic diagram illustrating an example of an inverter driver 100 in accordance with various examples of the present disclosure. As shown in FIG. 2, the inverter driver 100 includes an input 101 (A) and an output 109 (Z), two main big power transistors 122, 124 (MP, MN) which drive the output transitions between output states (e.g., “0” and “1” or logic low and logic high), two supporting small transistors 112, 114 (MPs, MNs) which maintain the output state after the output transitions, and several small control transistors 131, 133, 135, 137 (Mup, Mdwn, MGp, MGn) which enable/disable the two main big power transistors 122, 124 (MP, MN) and connect/disconnect the gates 105, 107 (gp, gn) of the two main big power transistors from the input 101 (A), and an inverting delay circuit 140 which provides a control signal 103 (sense) to the control transistors. The control signal 103 (sense) is an inverted delayed version of the signal at output 109 (Z).

Referring to FIG. 2, the two main big power transistors 122, 124 (MP, MN) are a set of output driving transistors. Transistors 122, 124 (MP, MN) are configured to drive the output transitions between two different output states (e.g., “0” and “1” or logic low and logic high) of the inverter (i.e., recharging or discharging the load capacitance). The first output driving transistor 122 (MP) is configured to drive the output transition from a first state (e.g., “0”) to a second state (e.g., “1”) and the second output driving transistor 124 (MN) is configured to drive the output transition from a second state (e.g., “1”) to a first state (e.g., “0”). The first output driving transistor 122 may be a transistor of a first type, e.g., PMOS. The second output driving transistor 124 may be a transistor of a second type, e.g., NMOS. Each output driving transistor is disabled when not driving the output transition. That is, the output driving transistors 122, 124 (MP, MN) are in the “OFF” state (i.e., deactivated) during the static output or non-transitioning period. The sizes of these transistors are defined by the required speed of the transition and load.

The two supporting small transistors 112, 114 (MPs, MNs) are a set of output sustaining transistors. Transistors 112, 114 (MPs, MNs) are configured to maintain the output state (e.g., “0” or “1”) at the output 109 (Z) of the inverter 100 between the output state transitions. That is, these transistors keep the output state of the inverter static (e.g., counteract the leakage current). The first output sustaining transistor 112 (MPs) is configured to maintain the output 109 (Z) at the second state (e.g., “1”) and the second output sustaining transistor 114 (MNs) is configured to maintain the output 109 (Z) at the first state (e.g., “0”). The first output sustaining transistor 112 may be a transistor of a first type, e.g., PMOS. The second output sustaining transistor 114 may be a transistor of a second type, e.g., NMOS. The sizes of these transistors may be the smallest possible size which still allow the transistors 112, 114 (MPs, MNs) to be able to sustain the output state of the inverter. These transistors do not contribute much to the transitions of the output because of their small size.

The two small transistors 131, 133 (Mup, Mdwn) are a set of gate control transistors which act as switches to keep the output driving transistors 112, 114 (MP, MN), respectively, in an “OFF” position when it is needed, i.e., after a transitioning period. In particular, the first gate control transistor 131 (Mup) when activated pulls-up the voltage at the first gate 105 (gp) of the first output driving transistor 122 (MP) (e.g., up to Vdd) and thereby disables the first output driving transistor 122 (MP). When the first gate control transistor 131 (Mup) is deactivated, the voltage at the first gate 105 (gp) may follow the voltage at the input 101 (A). Similarly, the second gate control transistor 133 (Mdwn) when activated pulls-down the voltage at the gate 107 (gn) of the second output driving transistor 124 (MN) (e.g., down to Vss) and thereby disables the second output driving transistor 124 (MN). When the second gate control transistor 133 (Mdwn) is deactivated, the voltage at the second gate 107 (gn) may follow the voltage at the input 101 (A). The first gate control transistor 131 may be a transistor of a first type, e.g., PMOS. The second gate control transistor 133 may be a transistor of a second type, e.g., NMOS.

The two small transistors 135, 137 (MGp, MGn) are a set of input control transistors which act as switches to connect the gates 105, 107 (gp, gn) of the output driving transistors 112, 114 (MP/MN), respectively, to the input 101 (A) when it is needed, i.e., during a transitioning period. In particular, the first input control transistor 135 (MGp) is configured to control when the first gate 105 (gp) of the first output driving transistor 122 (MP) is connected to the input 101 (A). That is, the first input control transistor 135 (MGp) when activated connects the gate 105 (gp) of the first output driving transistor 122 (MP) to the input 101 (A). Similarly, the second input control transistor 137 (MGn) is configured to control when the second gate 107 (gn) of the second output driving transistor 122 (MN) is connected to the input 101 (A). That is, the second input control transistor 137 (MGn) when activated connects the second gate 107 (gn) of the second output driving transistor 122 (MN) to the input 101 (A). The first input control transistor 135 may be a transistor of a second type, e.g., NMOS. The second input control transistor 137 may be a transistor of a first type, e.g., PMOS.

The inverting delay 140 is an inverting delay circuit which takes as input the signal at output 109 (Z) and provides as output a control signal 103 (sense) which is an inverted version of the signal at output 109 (Z) with a small propagation delay. The small propagation delay is configured to allow time for a respective output driving transistor to be enabled so as to drive the transition of the output state before the respective output driving transistor is disabled. For example, the inverting delay circuit may be three small conventional inverters connected in series.

In some instances, an inverter driver circuit consistent with FIG. 2 can also be described as including a first circuit path 151 extending between the input (A) and the output (Z), a second circuit path 153 extending in parallel with the first circuit path 151 between the input (A) and the output (Z), and a third circuit path 155 extending in parallel with the first circuit path 151 and the second circuit path 153 and arranged between the input (A) and the output (Z). For example, the first circuit path 151 can include an output sustaining circuit (e.g., 112, 114), the second circuit path 153 can include a first output driving circuit (e.g., 122, 131, 135), and the third circuit path 155 can include a second output driving circuit (e.g., 124, 133, 137). An input 156 of the inverting delay circuit 140 is coupled to the output (Z) of the inverter driver circuit and is coupled to an output of the first output driving circuit (e.g., drain of 122), and the output of the inverting delay circuit 157 on which the control signal 103 is provided is coupled to a first control terminal of the first output driving circuit (e.g., gates of 131, 135). The input 156 of the inverting delay circuit 140 is further coupled to an output of the second output driving circuit (e.g., drain of 124), and wherein the output 157 of the inverting delay circuit 140 is further coupled to a second control terminal of the second output driving circuit (e.g., gates of 133, 137).

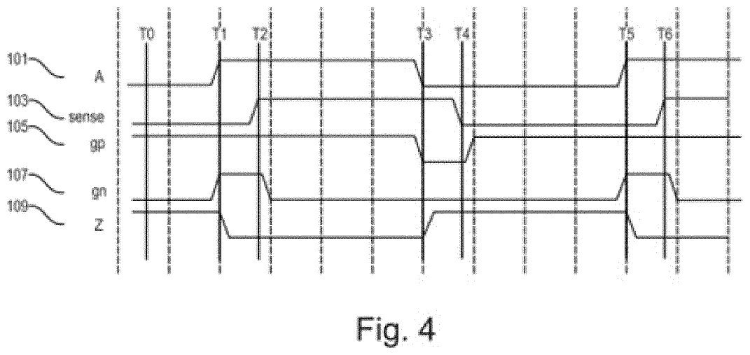

FIG. 4 is a timing diagram illustrating signal transitions of the digital signal driver circuit of FIG. 2 for three transition periods in accordance with various aspects of the present disclosure. That is, a first transition period (e.g., from T1 to T2) of the output signal from high to low in response to an input signal change from low to high, a second transition period (e.g., from T3 to T4) of the output signal from low to high in response to an input signal change from high to low, and a third transition period (e.g., from T5 to T6) of the output signal from high to low in response to an input signal change from low to high. Referring to FIG. 2, initially at time T0, the input signal at input 101 (A) is “0” (e.g., VSS or logic low), the output signal at output 109 (Z) is “1” (e.g., VDD or logic high), and the control signal 103 (sense) is “0”. The second output sustaining transistor 114 (MNs) is “OFF” (e.g., disabled) while the first output sustaining transistor 112 (MPs) is “ON” (e.g., enabled) thereby keeping the output signal at output 109 (Z) at “1”. The first input control transistor 135 (first input switch MGp) is switched off by the control signal 103 (sense) thereby disconnecting the first gate 105 (gp) of the first output driving transistor 122 (MP) from the input 101 (A) through the first input control transistor 135 (first input switch MGp). The first gate control transistor 131 (pull-up switch Mup) is switched on by the control signal 103 (sense) thereby pulling the voltage at the first gate 105 (gp) to the supply rail (e.g., Vdd) through the first gate control transistor 131 (switch Mup). Thus, the first output driving transistor 122 (MP) is “OFF”. The second input control transistor 137 (second input switch MGn) is switched on by the control signal 103 (sense) thereby connecting the second gate 107 (gn) of the second output driving transistor 124 (MN) to the input 101 (A) through the second input control transistor 137 (second input switch MGn). The second gate control transistor 133 (pull-down switch Mdwn) is switched off by the control signal 103 (sense). That is, at time T0, the pull-up switch Mup is “ON”, the pull-down switch Mdwn is “OFF”, the first input switch MGp is “OFF”, and the second input switch MGn is “ON”. In this state, the second output driving transistor 124 (MN) is controlled by the input signal at input 101 (A) which means that the second output driving transistor 124 (MN) is “OFF” because the input signal at T0 is “0”, but the second output driving transistor 124 (MN) is ready to drive a transition from “1” to “0”.

At time T1, the input signal at input 101 (A) transitions from a “0” to a “1”. That is, time T1 corresponds to a rising edge of the input signal. The input signal at input 101 (A) rises from “0” to “1”. The second gate 107 (gn) of the second output driving transistor 124 (MN) is still connected to the input 101 (A) and thus the voltage at the second gate 107 (gn) also rises from “0” to“1”. This transition causes the second output driving transistor 124 (MN) to activate (e.g., turn “ON”) and drive or discharge the output 109 (Z) from “1” to “0”. But the control signal 103 (sense) is still at “0” so the first output driving transistor 122 (MP) is still “OFF”. Consequently, there is no cross-current as the first output driving transistor 122 (MP) is “OFF” and there is no slow-down of the output transition because the second output driving transistor 124 (MN) does not have to counteract any effects from the first output driving transistor 122 (MP).

At time T2, the inverting delay 140 (as a delayed reaction to the change of state from “1” to “0” at output 109 (Z)) finally turns the control signal 103 (sense) at its output from “0” to “1”. This causes the second output driving transistor 124 (MN) to be disconnected from input 101 (A). That is, the control signal 103 (sense) disables the second input control transistor 137 (e.g., turns off the second input switch MGn) thereby disconnecting the second gate 107 (gn) of the second output driving transistor 124 (MN) from input 101 (A). The control signal 103 (sense) also enables the second gate control transistor 133 (e.g., turns on the pull-down switch Mdwn) so that the voltage at the second gate 107 (gn) is pulled down (e.g. to Vss) by the second gate control transistor 133 (pull-down switch Mdwn). Thus, the second output driving transistor 124 (MN) is “OFF”. At the same time, the control signal 103 (sense) enables the first input control transistor 135 (e.g., turns on the first input switch MGp) thereby connecting the first gate 105 (gp) of the first output driving transistor 122 (MP) to input 101 (A) through the first input control transistor 135 (first input control switch MGp). The control signal 103 (sense) disables the first gate control transistor 131 (e.g., turns off the first gate control switch (Mup)) so that the voltage at the first gate 105 (gp) follows the signal at input 101 (A). That is, at time T2, the pull-up switch Mup is “OFF”, the pull-down switch Mdwn is “ON”, the first input switch MGp is “ON”, and the second input switch MGn is “OFF”. In this state, the second output driving transistor 124 (MN) is controlled by the enabled second gate control transistor 133 (e.g., turned on Mdwn) which means the second output driving transistor 124 (MN) is “OFF”. The first output driving transistor 122 (MP) is controlled by the input signal at input 101 (A) which means that the first output driving transistor 122 (MP) is “OFF” because the input signal at T0 is “1”, but the first output driving transistor 122 (MP) is ready to drive a transition from “0” to “1”.

The first output sustaining transistor 112 (MPs) is “OFF” while the second output sustaining transistor 114 (MNs) is “ON” keeping output 109 (Z) at “0”. Thus, at time T2, the situation is inverted in comparison to the beginning state at time T0.

At time T3, the input signal transitions from a “1” to a “0”. That is, time T3 corresponds to a falling edge of the input signal. The input signal at input 101 (A) falls from “1” to “0”. The first gate 105 (gp) of the first output driving transistor 122 (MP) is still connected to the input 101 (A) and thus the voltage at the first gate 105 (gp) also falls from “1” to“0”. This transition causes the first output driving transistor 122 (MP) to activate (e.g., turn “ON”) and drive or charge the output 109 (Z) from “0” to “1”. But the control signal 103 (sense) is still at “1” so the second output driving transistor 124 (MN) is still “OFF”. Consequently, there is no cross-current as the second output driving transistor 124 (MN) is “OFF” and there is no slow-down of the output transition because the first output driving transistor 122 (MP) does not have to counteract any effects from the second output driving transistor 124 (MN).

At time T4, the inverting delay 140 (as a delayed reaction to the change of state from “0” to “1” at output 109 (Z)) finally turns the control signal 103 (sense) at its output from “1” to “0”. This causes the first output driving transistor 122 (MP) to be disconnected from input 101 (A). That is, the control signal 103 (sense) disables the first input control transistor 135 (e.g., turns off the first input switch MGp) thereby disconnecting the first gate 105 (gp) of the first output driving transistor 122 (MP) from input 101 (A). The control signal 103 (sense) also enables the first gate control transistor 131 (e.g., turns on the pull-up switch Mup) so that the voltage at the first gate 105 (gp) is pulled up (e.g. to Vdd) by the first gate control transistor 131 (pull-up switch Mup). Thus, the first output driving transistor 122 (MP) is “OFF”. At the same time, the control signal 103 (sense) enables the second input control transistor 137 (e.g., turns on the second input switch MGn) thereby connecting the second gate 107 (gn) of the second output driving transistor 124 (MN) to input 101 (A) through the second input control transistor 137 (second input control switch MGn). The control signal 103 (sense) disables the second gate control transistor 133 (e.g., turns off the second gate control switch (Mdwn)) so that the voltage at the second gate 107 (gn) follows the signal at input 101 (A). That is, at time T4, the pull-up switch Mup is “ON”, the pull-down switch Mdwn is “OFF”, the first input switch MGp is “OFF”, and the second input switch MGn is “ON”. In this state, the first output driving transistor 122 (MP) is controlled by the enabled first gate control transistor 131 (e.g., turned on Mup) which means the first output driving transistor 122 (MP) is “OFF”. The second output driving transistor 124 (MN) is controlled by the input signal at input 101 (A) which means that the second output driving transistor 124 (MN) is “OFF” because the input signal at T4 is “0”, but the second output driving transistor 124 (MN) is ready to drive a transition from “1” to “0”.

The first output sustaining transistor 112 (MPs) is “ON” while the second output sustaining transistor 114 (MNs) is “OFF” keeping output 109 (Z) at “1”. Thus, at time T4, the situation is the same as at the beginning state at time T0. The situations at times T5 and T6 are the same as the situations at times T1 and T2.

Referring to FIG. 4, the first and second output sustaining transistors 112, 114 (MPs, MNs) are configured to maintain the output state steady at output 109 (Z). The sizes of these transistors may be the smallest possible size which still allow the transistors 112, 114 (MPs, MNs) to be able to sustain the output state of the inverter. That is, these transistors are at least large enough to keep the output state of the inverter static (e.g., counteract the leakage current). These transistors do not contribute much to the transitions of the output because of their small size. The first and second output driving transistors 122, 124 (MP, MN) are larger than the first and second output sustaining transistors 112, 114 in order to drive the transition. The output driving transistors are sized for the load. The output driving transistors can have much a larger current flow. The larger current overcomes the capacitance faster thus allowing the inverter to change states quickly. Preferably, the size of the output driving transistors are ten or more times larger than the minimum size of the output sustaining transistors. However, in most cases, the size of the output sustaining transistor may be larger than the minimum required size to allow a substantial tolerance. In these cases, the size of the output driving transistors may be 5 or more times larger than the size of the output sustaining transistors. The sizes of the control transistors 131, 133, 135, 137 may be about the same size as the output sustaining transistors. All other transistors (e.g., the gate control transistors and the input control transistors) in circuit can be the minimum size allowed by technology size (that is, fabrication size process, such as 20 nm process, 14 nm process, etc.). Accordingly, the sizes of the sustaining and control transistors can be reduced down to the minimum technology allowed size, while the sizes of the output driving transistors are usually more than 10 times the minimum technology allowed size. And in some cases when needed the sizes of the output driving transistors may be at least more than 5 times the minimum technology allowed size.

In general, when sizing CMOS transistor pairs, a P/N ratio is usually defined by the design need on the propagation symmetry of falling/rising edges. For simplicity it is advised to use the same P/N ratio as for other digital circuits and components used in design. This ratio may be used for the output sustaining transistors 112, 114 (MPs/MNs) and for the output driving transistors 122, 124 (MP/MN). This ratio may also be used for the gate and input control transistors 131, 133, 135, 137 (Mup/Mdwn/MGp/MGn).

The present disclosure describes an inverter that is scalable. In general, larger transistors mean a larger current to overcome the load capacitance and therefore the faster the transition. However, in a conventional inverter once the transistors are large enough to be in saturation no further speed up is possible due to the countering effects of the opposing transistors. Because the output driving transistors of the inverter of the present disclosure are dynamically and independently connected, the speed up can be scaled even further beyond the typical saturation point.

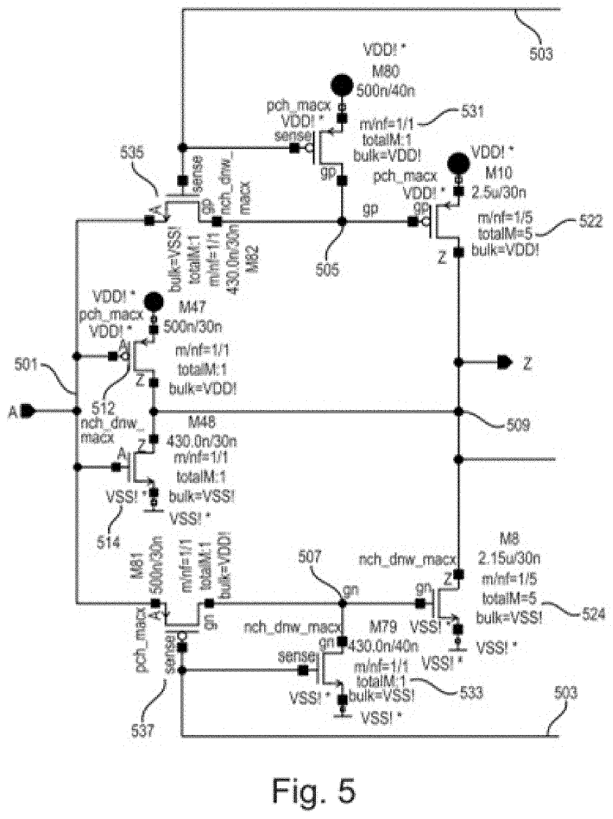

FIG. 5 is a schematic diagram illustrating a first circuit portion of the digital signal driver circuit of FIG. 2 in accordance with various aspects of the present disclosure. For example, the first output sustaining transistor 512 may be a PMOS transistor having a channel width of 500 nm and a channel length of 30 nm and the second output sustaining transistor 514 may be an NMOS transistor having a channel width of 430 nm and a channel length of 30 nm. The first output driving transistor 522 may be a PMOS transistor having a channel width of 2500 nm and a channel length of 30 nm and the second output driving transistor 524 may be an NMOS transistor having a channel width of 2150 nm and a channel length of 30 nm. The first gate control transistor 531 may be a PMOS transistor having a channel width of 500 nm and a channel length of 40 nm and the second gate control transistor 533 may be an NMOS transistor having a channel width of 430 nm and a channel length of 40 nm. The first input control transistor 535 may be an NMOS transistor having a channel width of 430 nm and a channel length of 30 nm and the second input control transistor 537 may be a PMOS transistor having a channel width of 500 nm and a channel length of 30 nm.

The inverting delay circuit 140 may be three small simple inverters connected in series. The size of the transistors of these small simple inverters may be the same size as the output sustaining transistors. That is, each inverter includes a PMOS transistor having a channel width of 500 nm and a channel length of 30 nm and an NMOS transistor having a channel width of 430 nm and a channel length of 30 nm. The sizes of the transistors of the small simple inverters in the inverting delay circuit 140 may be the minimum technology allowed size.

The specific sizes of the transistors of the inverter circuit of the present disclosure are only provided as an example. The sizes of the transistors are not limited to these specific sizes. The actual sizes of the transistor depend on the fabrication process technology used.

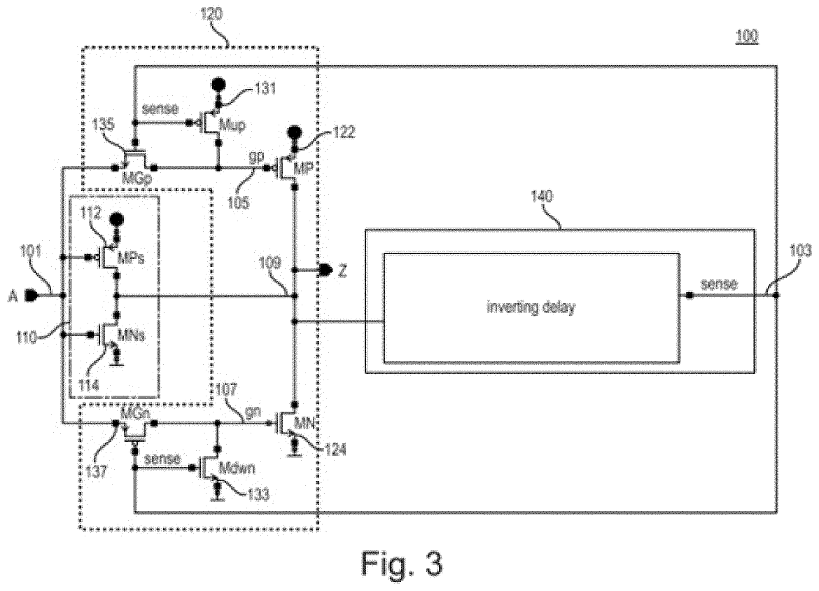

FIG. 3 is another schematic diagram illustrating a digital signal driver circuit in accordance with various aspects of the present disclosure. Referring to FIG. 3, a first portion of the inverter 100 of the present disclosure may be characterized as two circuit paths between input 101 (A) and output 109 (Z). The first circuit path 110 (i.e., the sustaining portion) includes the two output sustaining transistors 112, 114 (MPs, MNs) arranged as an inverter with input 101 (A) and output 109 (Z). The second circuit path 120 (i.e., the driving portion) includes the two output driving transistors 122, 124 (MP, MN) arranged as an inverter with input 101 (A) and output 109 (Z) with additional transistors configured as control switches 131, 133, 135, 137 to connect/disconnect and enable/disable each respective output driving transistor independently. That is, the first circuit path 110 is static and does not change and the second circuit path 120 is dynamic. The switches in the second circuit path is controlled by the control signal 103 (sense) so that only one output driving transistor is connected to the input 101 (A) and/or is enabled at a time. One advantage of this arrangement is a reduced input capacitance. First, first circuit path has a much smaller gate capacitance because the output sustaining transistors are much smaller than the output driving transistors and gate capacitance is proportional to the area of the gate (that is, the gate width multiplied by the gate length). Second, only the gate of one of the output driving transistors is connected.

As shown in FIG. 3, the first circuit path 110 is a sustaining portion which includes a smaller version of the simple inverter to provide the correct output states in static cases. The second circuit path 120 is a driving portion which includes the driving transistors which are independently connected and controlled.

The driving transistors are separately controlled so as to be individually connected. For example, the larger driving transistors of the present inverter 122, 124 (MP, MN) are separated and their gates 105, 107 (gp, gn) are controlled individually. The first input gate 105 (gp) is connected to input 101 (A) through the first input control transistor 135 (MGp) which is an analog switch controlled by the control signal 103 (sense). The second input gate 107 (gn) is connected to input 101 (A) through the second input control transistor 137 (MGn) which is another analog switch controlled by the control signal 103 (sense). The switches are of different types (e.g., PMOS vs NMOS) so even though they are controlled by the same control signal only one output driving transistor is connected to the input at a time. This reduces the input capacitance of the inverter circuit because the capacitance of the disconnected gate is removed and only a small enabled switch capacitance of the opposing gate is added to the input capacitance instead. The disconnected gate of the output driving transistor is pulled to the source with the gate control transistors 131, 133 (Mup, Mdwn) (e.g., “OFF” switch) in order to keep the disconnected transistor off. As only one output driving transistor can be activated at a time, there is no cross-current power loss. As soon as the input voltage moves and becomes larger than the threshold of the active output driving transistor, the output starts to be recharged immediately by the active output driving transistor and no charge is lost on cross-current. When the output successfully moves to the opposite state, the inverting delay circuit 140 senses it and after some delay (to complete the output state transition) swap the active and switched-off transistors.

For example, referring to FIG. 4, when the inverter is in steady state at time T0, the output 109 (Z) is controlled by the output of the first circuit path 110. From time T1 to time T2, when the input transitions from a “0” to a “1”, the output 109 (Z) is controlled by the output of the bottom half of the second circuit path 120 as shown in FIG. 3. That is, from input 101 (A) through the second input control transistor 137 (switch MGn) through the second output driving transistor 124 (MN) to output 109 (Z). During this time, upper half of the second circuit path is disconnected and disabled. When the inverter is in steady state again from time T2 to time T3, the output 109 (Z) is controlled by the output of the first circuit path 110. From time T3 to time T4, when the input transitions from a “1” to a “0”, the output 109 (Z) is controlled by the output of the upper half of the second circuit path 120 as shown in FIG. 3. That is, from input 101 (A) through the first input control transistor 135 (switch MGp) through the first output driving transistor 122 (MP) to output 109 (Z). During this time, lower half of the second circuit path is disconnected and disabled.

Referring again to FIG. 3, the inverting delay circuit 140 is not limited to the simple inverting delay circuit illustrated in FIG. 2. The inverting delay circuit 140 may be any circuit which takes as input the signal at output 109 (Z) and provides as output a control signal 103 (sense) which is an inverted version of the signal at output 109 (Z) with a small propagation delay.

The inverting delay provides two functions, the delay aspect allows time for the transition to occur. In the driving portion, a level change at the input 101 (A) activates the transition circuit. The output driving transistor stays “ON” long enough to drive the transition to completion because the sustaining portion cannot drive the transition. After the transition period, the output should be in a stable state (i.e., either high or low). To reduce power consumption, the inverted signal aspect provides the control to disengage the driving transistors. That is, after the transition period the delayed inverted signal disconnects and disables the output driving transistor. The inverting delay may provide a 1-2 gate delay.

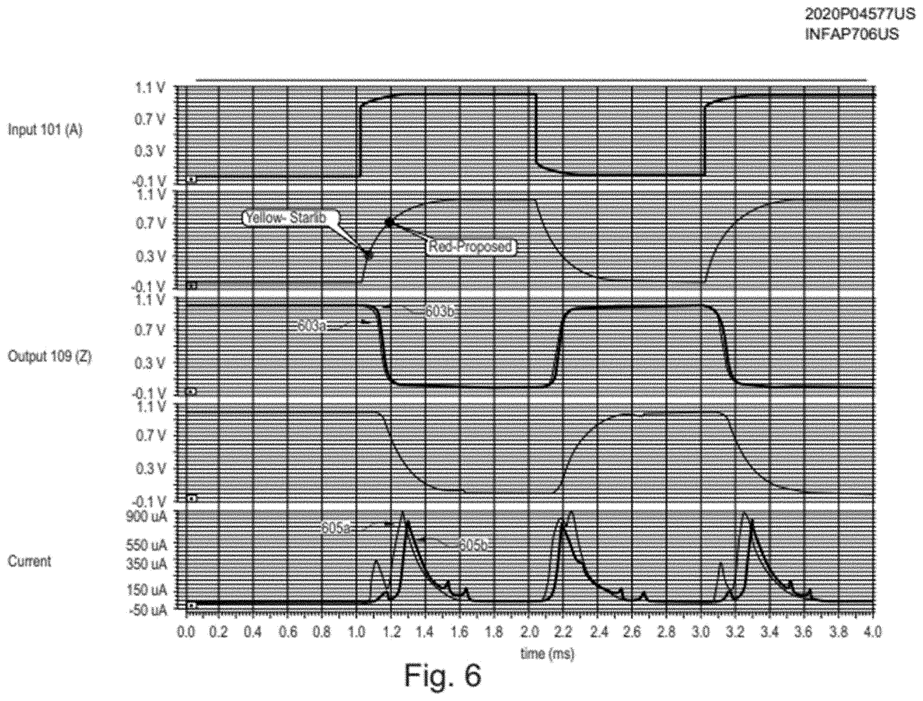

FIG. 6 is a transient response diagram comparing the signal transitions of a conventional inverter driver circuit to the signal transitions of the digital signal driver circuit of FIG. 2 in accordance with various aspects of the present disclosure. The input voltage at node A toggles between 0 V and 1.1 V. The output voltage at node Z toggles in the inverted direction being delayed compared to the signal at node A. Referring to FIG. 6, the curve indicated by reference numeral 603a shows the output signal of a conventional simple inverter and the curve indicate by reference numeral 603b shows the output signal of an example inverter of the present disclosure with respect to the input voltage. As shown in FIG. 6, the curve indicated by reference numeral 605a shows the current consumed by a conventional simple inverter and the curve indicate by reference numeral 605b shows the current consumed by an example inverter of the present disclosure during the transition periods. The results of the transient analysis show the integral of the current over time is larger for the conventional inverter than the respective integral for the inverter.

In the following, various aspects of this disclosure will be illustrated:

Example 1 is an inverter driver circuit. The inverter circuit may include an input configured to receive an input signal; an output configured to provide an output signal; a parallel circuit between the input and the output, wherein the parallel circuit includes a first circuit path parallel to a second circuit path between the input and the output, wherein the first circuit path includes an output sustaining circuit and the second circuit path includes an output driving circuit; and an inverting delay circuit coupled to the output of the inverter driver circuit and coupled to the output driving circuit, wherein the inverting delay circuit is configured to provide a control signal to the output driving circuit, wherein the control signal is a delayed and inverted version of the output signal.

In Example 2, the inverter driver circuit of Example 1, can optionally include wherein the output sustaining circuit includes a first output sustaining transistor and a second output sustaining transistor, wherein the gates of the first and the second output sustaining transistor are continuously operatively connected to the input and the drains of the first and second output sustaining transistors are continuously operatively connected to the output. That is, the input and the output are configured to be operatively continuously connected through the first circuit path.

In Example 3, the inverter driver circuit of Examples 1 or 2, can optionally include wherein the output driving circuit includes a first output driving transistor, a second output driving transistor, and a control circuitry, wherein the control circuitry dynamically controls the first output driving transistor and the second driving transistor based on the control signal.

In Example 4, the inverter driver circuit of Example 3, can optionally include wherein the control circuitry is configured to operatively connect the input to only one of the gates of the first and the second output driving transistor at a time and to enable only one of the first and second output driving transistors at a time. That is only one or none of the gates of the first and the second output driving transistor is connected to the input at any time. And the first and second output driving transistors cannot be active simultaneously. That is, the input and the output are configured to be operatively only temporarily connected through the second circuit path.

In Example 5, the inverter driver circuit of any of Examples 1 to 4, can optionally include wherein the second circuit path includes a first subpath and a second subpath, wherein the first subpath is parallel to the second subpath between the input and the output, wherein the first subpath includes the first output driving transistor and the second subpath includes the second output driving transistor, wherein the input and the output are configured to be operatively connected through the first subpath or the second subpath but not both the first subpath and the second subpath. That is, the input and the output are configured to be operatively connected through only one of the first and second subpaths of the second circuit path at a time and on a temporary basis.

In Example 6, the inverter driver circuit of any of Examples 3-5, can optionally include wherein the control circuitry includes a first input control switch connected to the input and the gate of the first output driving transistor and includes a second input control switch connected to the input and the gate of the second output driving transistor, wherein when the first input control switch is enabled the gate of the first output driving transistor is operatively connected to the input and when the second input control switch is enabled the gate of the second output driving transistor is operatively connected to the input.

In Example 7, the inverter driver circuit of any of Examples 3 to 6, can optionally include wherein the control circuitry includes a first gate control switch connected to the gate of the first output driving transistor and a second gate control switch connected to the gate of the second output driving transistor, wherein when the first gate control switch is enabled the first output driving transistor is disabled and when the second gate control switch is enabled the second output driving transistor is disabled.

In Example 8, the inverter driver circuit of Examples 6 and 7, wherein the first input control switch, the second input control switch, the first gate control switch, and the second gate control switch are each a transistor with their respective gates controlled by the control signal.

In Example 9, the inverter driver circuit of Example 8, can optionally include wherein the second circuit path includes a first subpath and a second subpath, wherein the first subpath is parallel to the second subpath between the input and the output, wherein the first subpath includes the first input control transistor and the first output driving transistor, wherein the second subpath includes the second input control transistor and the second output driving transistor, wherein the input and the output are configured to be operatively connected through the first subpath or the second subpath but not both the first subpath and the second subpath.

In Example 10, the inverter driver circuit of Example 9, can optionally include wherein the input and the output are configured to be operatively connected through the first subpath or the second subpath only when the input or the output is changing.

In Example 11, the inverter driver circuit of Example 10, can optionally include wherein only the output sustaining circuit is operatively connected to the output when the input and the output are stable.

In Example 12, the inverter driver circuit of Example 10, can optionally include wherein the first output sustaining transistor, the first output driving transistor, the first gate control transistor, and the second input control transistor are transistors of a first type, wherein the second output sustaining transistor, the second output driving transistor, the second gate control transistor, and the first input control transistor are transistors of a second type.

In Example 13, the inverter driver circuit of Example 11, can optionally include wherein transistors of the first type are PMOS transistors and wherein transistors of the second type are NMOS transistors.

In Example 14, the inverter driver circuit of any of Examples 1 to 13, can optionally include wherein the sizes of the output driving transistors are at least five times larger than the sizes of the output sustaining transistors.

In Example 15, the inverter driver circuit of Example 14, wherein the sizes of the control transistors are substantially the same as the sizes of the output sustaining transistors.

Example 16 is an inverter driver circuit. The inverter driver circuit may include an input configured to receive an input signal; an output configured to provide an output signal; a first output providing circuit on a first circuit path configured to continuously drive the output in dependence of the input signal; a second output providing circuit on a second circuit path configured to temporarily drive the output only during a transition period of the output signal, wherein the transition period is a period after the input signal has changed; and an inverting delay circuit coupled to the output and the second output providing circuit on the second circuit path, wherein the inverting delay circuit is configured to provide a delayed version of the output signal to disable the second output providing circuit on the second circuit path after the transition period has expired. The inverting delay circuit may also be configured to provide a delayed and inverted version of the output signal.

In Example 17, the inverter driver circuit of Example 16, can optionally include wherein the second output providing circuit includes a first output driving transistor and a second output driving transistor, each having a control circuit receiving the delayed version of the output signal, wherein, during the transition period, only one of the control circuits is activated so that only one of the output driving transistors is driven by the input signal. Each control circuit may also be configured to receive a delayed and inverted version of the output signal.

In Example 18, the inverter driver circuit of Example 17, can optionally include wherein each control circuit includes a respective input switch between the input and a respective one of the output driving transistors, wherein each input switch is controlled by a same signal and wherein each input switch has a different activation polarity, so that during the transition period only one of the respective output driving transistors is connected to the input. The same signal may be the delayed or the delayed and inverted version of the output signal.

### Terminology

For the purposes of the present document, the following terms and definitions are applicable to the examples and embodiments discussed herein.

The term “circuitry” as used herein refers to, is part of, or includes hardware components such as an electronic circuit or a logic circuit that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system).

The terms “coupled,” “connected”, “electrically coupled,” and “electrically connected” along with derivatives thereof are used herein. The terms “coupled” or “connected” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another.

What is claimed is:

1. An inverter driver circuit comprising:
an input configured to receive an input signal;
an output configured to provide an output signal;
a parallel circuit between the input and the output, wherein the parallel circuit includes a first circuit path parallel to a second circuit path between the input and the output, wherein the first circuit path includes an output sustaining circuit and the second circuit path includes an output driving circuit; and
an inverting delay circuit coupled to the output of the inverter driver circuit and coupled to the output driving circuit, wherein the inverting delay circuit is configured to provide a control signal to the output driving circuit, wherein the control signal is a delayed and inverted version of the output signal.

2. The inverter driver circuit of claim 1, wherein the output sustaining circuit includes a first output sustaining transistor and a second output sustaining transistor, wherein gates of the first and the second output sustaining transistor are continuously operatively connected to the input and drains of the first and second output sustaining transistors are continuously operatively connected to the output.

3. The inverter driver circuit of claim 2, wherein the output driving circuit includes a first output driving transistor, a second output driving transistor, and a control circuitry, wherein the control circuitry dynamically controls the first output driving transistor and the second output driving transistor based on the control signal.

4. The inverter driver circuit of claim 3, wherein the control circuitry is configured to operatively connect the input to only one of the gates of the first and the second output driving transistor or none of the gates at a time and to enable only one of the first and second output driving transistors at a time.

5. The inverter driver circuit of claim 3, wherein the second circuit path includes a first subpath and a second subpath, wherein the first subpath is parallel to the second subpath between the input and the output, wherein the first subpath includes the first output driving transistor and the second subpath includes the second output driving transistor, wherein the input and the output are configured to be operatively connected through the first subpath or the second subpath but not both the first subpath and the second subpath.

6. The inverter driver circuit of claim 3, wherein the control circuitry includes a first input control switch connected to the input and a gate of the first output driving transistor and includes a second input control switch connected to the input and a gate of the second output driving transistor, wherein when the first input control switch is enabled the gate of the first output driving transistor is operatively connected to the input and when the second input control switch is enabled the gate of the second output driving transistor is operatively connected to the input.

7. The inverter driver circuit of claim 6, wherein the control circuitry includes a first gate control switch connected to the gate of the first output driving transistor and a second gate control switch connected to the gate of the second output driving transistor, wherein when the first gate control switch is enabled the first output driving transistor is disabled and when the second gate control switch is enabled the second output driving transistor is disabled.

8. The inverter driver circuit of claim 7, wherein the first input control switch, the second input control switch, the first gate control switch, and the second gate control switch are each a transistor with their respective gates controlled by the control signal.

9. The inverter driver circuit of claim 8, wherein the second circuit path includes a first subpath and a second subpath, wherein the first subpath is parallel to the second subpath between the input and the output, wherein the first subpath includes the first input control switch and the first output driving transistor, wherein the second subpath includes the second input control switch and the second output driving transistor, wherein the input and the output are configured to be operatively connected through the first subpath or the second subpath but not both the first subpath and the second subpath.

10. The inverter driver circuit of claim 9, wherein the input and the output are configured to be operatively connected through the first subpath or the second subpath only when the input or the output is changing.

11. The inverter driver circuit of claim 10, wherein only the output sustaining circuit is operatively connected to the output when the input and the output are stable.

12. The inverter driver circuit of claim 10, wherein the first output sustaining transistor, the first output driving transistor, the first gate control switch, and the second input control switch are transistors of a first type, wherein the second output sustaining transistor, the second output driving transistor, the second gate control switch, and the first input control switch are transistors of a second type.

13. The inverter driver circuit of claim 12, wherein transistors of the first type are PMOS transistors and wherein transistors of the second type are NMOS transistors.

14. The inverter driver circuit of claim 3, wherein the sizes of the output driving transistors are at least five times larger than the sizes of the output sustaining transistors.

15. The inverter driver circuit of claim 7, wherein the input control switches are control transistors, and the sizes of the control transistors are substantially the same as the sizes of the output sustaining transistors.

16. An inverter driver circuit comprising:
an input configured to receive an input signal;
an output configured to provide an output signal;
a first output providing circuit on a first circuit path configured to continuously drive the output in dependence of the input signal;
a second output providing circuit on a second circuit path configured to temporarily drive the output only during a transition period of the output signal, wherein the transition period is a period after the input signal has changed; and
an inverting delay circuit coupled to the output and the second output providing circuit on the second circuit path, wherein the inverting delay circuit is configured to provide a delayed version of the output signal to disable the second output providing circuit on the second circuit path after the transition period has expired.

17. The inverter driver circuit of claim 16, wherein the second output providing circuit comprises a first output driving transistor and a second output driving transistor, each having a control circuit receiving the delayed version of the output signal, wherein, during the transition period, only one of the control circuits is activated so that only one of the output driving transistors is driven by the input signal.

18. The inverter driver circuit of claim 17, wherein each control circuit comprises a respective input switch between the input and a respective one of the output driving transistors, wherein each input switch is controlled by a same signal and wherein each input switch has a different activation polarity, so that during the transition period only one of the respective output driving transistors is connected to the input.

19. An inverter driver circuit comprising:
an input;
an output;
a first circuit path extending between the input and the output, the first circuit path comprising an output sustaining circuit;
a second circuit path extending in parallel with the first circuit path between the input and the output, wherein the second circuit path includes a first output driving circuit; and
an inverting delay circuit having an input and an output, wherein the input of the inverting delay circuit is coupled to the output of the inverter driver circuit and is coupled to an output of the first output driving circuit, and wherein the output of the inverting delay circuit is coupled to a first control terminal of the first output driving circuit.

20. The inverter driver circuit of claim 19, further comprising:
a third circuit path extending in parallel with the first circuit path and the second circuit path and arranged between the input and the output, wherein the third circuit path includes a second output driving circuit; and
wherein the input of the inverting delay circuit is further coupled to an output of the second output driving circuit, and wherein the output of the inverting delay circuit is further coupled to a second control terminal of the second output driving circuit.

21. The inverter driver circuit of claim 19, wherein the first output driving circuit comprises:
a first control transistor having a first source, a first gate, and a first sink, wherein the first source is coupled to the input of the inverter driver circuit and the first gate is coupled to the output of the inverting delay circuit;
a second control transistor having a second source, a second gate, and a second sink, wherein the second source is coupled to a DC supply terminal, the second gate is coupled to the output of the inverting delay circuit, and the second sink is coupled to the first sink; and
an output driving transistor having an output driving source, an output driving gate, and an output driving sink, wherein the output driving source is coupled to the DC supply terminal, the output driving gate is coupled to the first sink, and the output driving sink is coupled to output of the inverter driver circuit.
